(19) United States
(12) Patent Application Publication
(10) Pub. No.: US 2012/0193663 A1
(43) Pub. Date: Aug. 2, 2012

(54) LIGHT EMITTING DIODE AND FABRICATION METHOD THEREOF

(75) Inventor: Chia-En LEE, Hsinchu (TW)

(73) Assignee: LEXTAR ELECTRONICS CORP., Hsinchu (TW)

(21) Appl. No.: 13/323,327

(22) Filed: Dec. 12, 2011

(30) Foreign Application Priority Data
Feb. 1, 2011 (TW) 100103999

(51) Int. Cl. H01L 33/60

(52) U.S. Cl. 257/98; 438/29; 257/E33.072

(57) ABSTRACT

A fabrication method of a light-emitting diode including forming an epitaxial layer on a first substrate; forming a metal pad and a stress release ring on the epitaxial layer, wherein the stress release ring surrounds the metal pad; performing a substrate replacement process to transfer the epitaxial layer, the metal pad, and the stress release ring onto a second substrate, wherein the metal pad and the stress release ring are disposed between the epitaxial layer and the second substrate; patterning the epitaxial layer to expose a portion of the stress release ring; and removing the stress release ring to suspend a portion of the epitaxial layer. Moreover, a light emitting diode is provided.

### CROSS REFERENCE TO RELATED APPLICATIONS

This application claims the benefit of Taiwan Application No. 100103999 filed on Feb. 1, 2011, and the entirety of which is incorporated by reference herein.

### BACKGROUND OF THE INVENTION

1. Field of the Invention

The present invention relates to a light-emitting diode, and in particular relates to a fabrication method of a light-emitting diode using substrate replacement processes and the light-emitting diode fabricated thereby.

2. Description of the Related Art

Various lighting devices have advanced with the development and advances in technologies to satisfy customers in the modern world. Among the various lighting devices, there has been a trend for light-emitting diodes to gradually replace traditional lighting devices (for example, fluorescent lamps and incandescent lights) due to advantages such as lower heat generation, lower energy consumption, longer lifespans, and smaller volumes. FIGS. 1A through 1C illustrate a flow chart of a conventional method for fabricating a light-emitting diode. Referring to FIG. 1A, in the prior art, an epitaxial layer 120 is first formed on an epitaxial substrate 110, and then, a metal layer 130 is formed on the epitaxial layer 120. Then, as shown in FIG. 1B, the epitaxial layer 120 and the metal layer 130 are transferred onto a supporting substrate 140 to obtain a light-emitting diode 100, wherein the step of transferring involves first bonding the metal layer 130 to the metal layer 142 on the supporting substrate 140 and, as shown in FIG. 1C, removing the epitaxial layer 120.

When implementing the substrate replacement process, it is necessary to implement the process under high temperatures, such that the epitaxial layer 120 and the supporting substrate 140 undergo greater thermal expansion. After the process, both the epitaxial layer 120 and the supporting substrate 140 cool down and contract. In addition, when the light-emitting diode 100 emits light, the epitaxial layer 120 and the supporting substrate 140 undergo thermal expansion. On the other hand, when the light-emitting diode 100 stops emitting light, the epitaxial layer 120 and the supporting substrate 140 cool down and contract. However, since the coefficient of thermal expansion of the supporting substrate 140 is considerably smaller than that of the epitaxial layer 120, large residual stress remains in the epitaxial layer 120 after it has cooled down, causing the characteristics and lifespan of elements of the light-emitting diode 100 to degrade.

### BRIEF SUMMARY OF THE INVENTION

The invention provides a fabrication method of a light-emitting diode for improving the characteristics of its elements and increasing its lifespan.

The invention also provides a light-emitting diode for improving the characteristics of its elements and increasing its lifespan.

The invention provides a fabrication method of a light-emitting diode, comprising: forming an epitaxial layer on a first substrate; forming a metal pad and a stress release ring on the epitaxial layer, wherein the stress release ring surrounds the metal pad; performing a substrate replacement process to transfer the epitaxial layer, the metal pad, and the stress release ring onto a second substrate, wherein the metal pad and the stress release ring are disposed between the epitaxial layer and the second substrate; patterning the epitaxial layer to expose a portion of the stress release ring; and removing the stress release ring to suspend a portion of the epitaxial layer.

In an embodiment of the invention, the fabrication method further includes, before the substrate replacement process, forming a barrier layer covering the metal pad and filling into a gap between the metal pad and the stress release ring.

In an embodiment of the invention, the barrier layer further covers the stress release ring.

In an embodiment of the invention, the metal pad is a reflective layer.

In an embodiment of the invention, the metal pad is in contact with the stress release ring.

In an embodiment of the invention, a thickness of the stress release ring is 500-5000 angstroms.

In an embodiment of the invention, the stress release ring is formed of a material selected from the group consisting of silicon dioxide, silicon nitride, photoresist, sol-gel, silicon, and aluminum oxide.

In an embodiment of the invention, the suspended portion of the epitaxial layer has a shape of a ring.

In an embodiment of the invention, a thickness of the epitaxial layer is D1, and a width of the ring is D2, wherein 0.1×D1>D2>0.05×D1.

In an embodiment of the invention, the substrate replacement process includes: forming a metal layer on the metal pad and the stress release ring, and forming another metal layer on the second substrate; bonding the metal layer on the stress release ring and the metal pad to the metal layer on the second substrate; and removing the first substrate.

The invention also provides a light-emitting diode, comprising: a substrate; a metal layer disposed on the substrate; a metal pad disposed on the metal layer; and an epitaxial layer disposed on the metal pad, wherein the edges of the epitaxial layer protrude out from the metal pad, forming a suspended portion.

In an embodiment of the invention, a distance between the suspended portion of the epitaxial layer and the metal layer is 500-5000 angstroms.

In an embodiment of the invention, the suspended portion of the epitaxial layer has a shape of a ring.

In an embodiment of the invention, a width of the epitaxial layer is D1, and a width of the ring is D2, wherein 0.1×D1>D2>0.05×D1.

In an embodiment of the invention, the light-emitting diode further comprises a barrier layer disposed between the metal pad and the metal layer and covering the edges of the metal pad, wherein the suspended portion of the epitaxial layer protrudes out from the barrier layer.

In an embodiment of the invention, the light-emitting diode further comprises a barrier layer disposed between the metal pad and the metal layer and covering the edges of the metal pad, wherein a portion of the barrier layer extends below the suspended portion of the epitaxial layer, and the distance between the suspended portion of the epitaxial layer and the barrier is 500-5000 angstroms.

In an embodiment of the invention, the metal pad is a reflective layer.

In the fabrication method of light-emitting diodes of the invention, a stress release ring is formed first, and then a substrate replacement process is implemented, which is followed by the removal of the stress release ring for obtaining an epitaxial layer with a suspended portion. Since the epitaxial layer of the light-emitting diode fabricated according to the invention has a suspended portion, when the epitaxial layer expands due to heat, the suspended portion has sufficient room for expansion, thus reducing the residual stress in the epitaxial layer due to thermal expansion and contraction. Therefore, the light-emitting diode of this embodiment has superior characteristics and a longer lifespan.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A through 1C illustrate a flow chart of a conventional method for fabricating a light-emitting diode;

FIGS. 2A through 2E illustrate a flow chart of a conventional method for fabricating a light-emitting diode according to an embodiment of the invention;

FIG. 3 illustrates the top view of the light-emitting diode shown in FIG. 2E.

FIG. 4 illustrates a light emitting diode according to another embodiment of the invention;

FIG. 5 illustrates one of the steps of a fabrication method of a light-emitting diode according to another embodiment of the invention;

FIG. 6 illustrates a light emitting diode according to another embodiment of the invention; and

FIG. 7 illustrates one of the steps of a fabrication method of a light-emitting diode according to another embodiment of the invention.

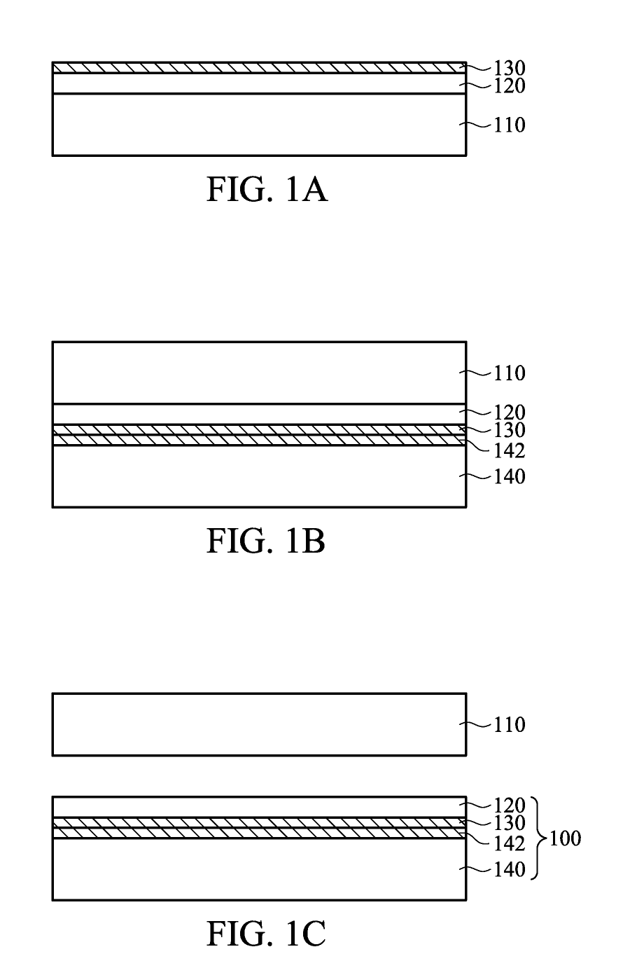

### DETAILED DESCRIPTION OF THE INVENTION

The following description is of the best-contemplated mode of implementing the invention. This description is made for the purpose of illustrating the general principles of the invention and should not be taken in a limiting sense. The scope of the invention is best determined by reference to the appended claims.

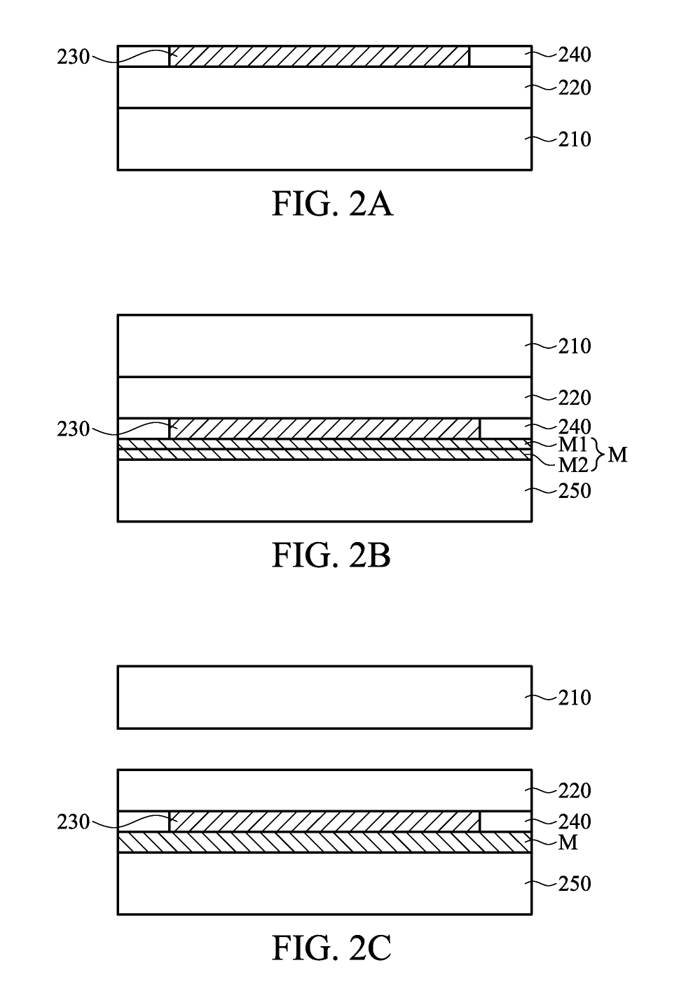

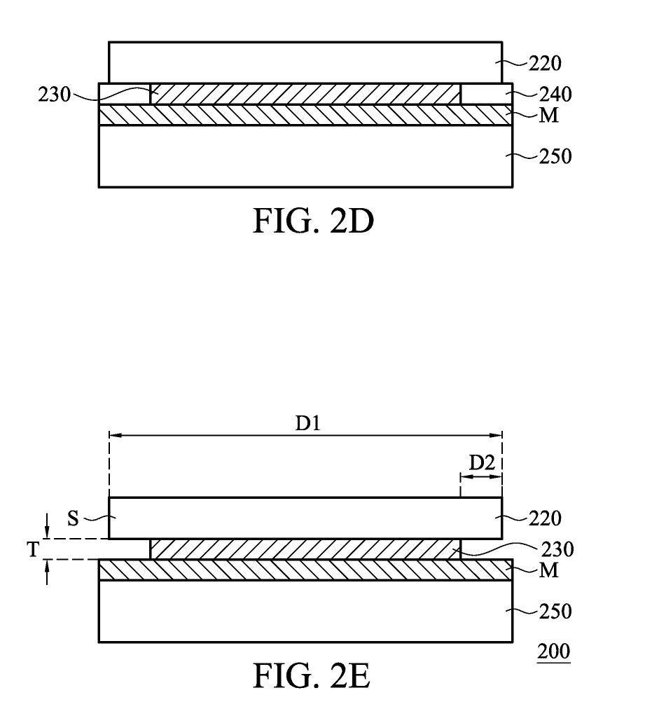

FIGS. 2A through 2E illustrate a flow chart of a fabrication method for a light-emitting diode according to an embodiment of the invention. Referring to FIG. 2A, the fabrication method includes the following steps. First, an epitaxial layer 220 is formed on a substrate 210 (i.e. the first substrate). The substrate 210 may be formed of aluminum oxide, for example but is not limited thereto. In addition, the epitaxial layer 220 is formed by stacking a plurality of film layers. In the case of GaN based light-emitting diodes, the epitaxial layer 220 includes n-type GaN, p-type GaN, and a quantum well located between the n-type GaN and the p-type GaN. The method of forming epitaxial layer 220 is already known by one skilled in the art and will not be described herein.

Then, a metal pad 230 and a stress release ring 240 are formed on the epitaxial layer 220, wherein the stress release ring 240 surrounds the metal pad 230. In this embodiment, there are no restrictions on the order in which the metal pad 230 and the stress release ring 240 are formed. That is to say, the stress release ring 240 may be formed prior to the formation of metal pad 230, or the metal pad 230 may be formed prior to the formation of stress release ring 240. In addition, in this embodiment, the metal pad 230 may be for example in contact with the stress release ring 240. The thickness of the stress release ring 240 may be for example 500-5000 angstroms, and the stress release ring 240 may be formed of a material selected from the group consisting of silicon dioxide, silicon nitride, photoresist, sol-gel, silicon, and aluminum oxide.

Then, as shown in FIG. 2B, a substrate replacement process is implemented for transferring the epitaxial layer 220, the metal pad 230, and the stress release ring 240 onto another substrate 250 (i.e. the second substrate). The substrate 250 may be formed of silicon, copper, etc. but not limited thereto. Further, when implementing the substrate replacement process, the following is implemented first: a metal layer M1 is formed on the metal pad 230 and the stress release ring 240, and a metal layer M2 is formed on the substrate 250. Then, the metal layer M1 on the metal pad 230 and the stress release ring 240 to the metal layer M2 on the substrate 250 are bonded together. After bonding the metal layers M1 and M2, the combination of the metal layers M1 and M2 may be considered as a single metal layer M.

Then, as shown in FIG. 2C, the substrate 210 is removed for transferring the epitaxial layer 220, the metal pad 230, and the stress release ring 240 onto the second substrate so that metal pad 230 and stress release ring 240 may be located between the epitaxial layer 220 and the substrate 250. In addition, for removing the substrate 210, a method such as a laser lift-off process may be used.

Then, as shown in FIG. 2D, the epitaxial layer 220 is patterned to expose a portion of the stress release ring 240. Then, as shown in FIG. 2E, the stress release ring is removed so that the portion of the epitaxial layer 220 is suspended. As such, the light emitting diode 220 is obtained.

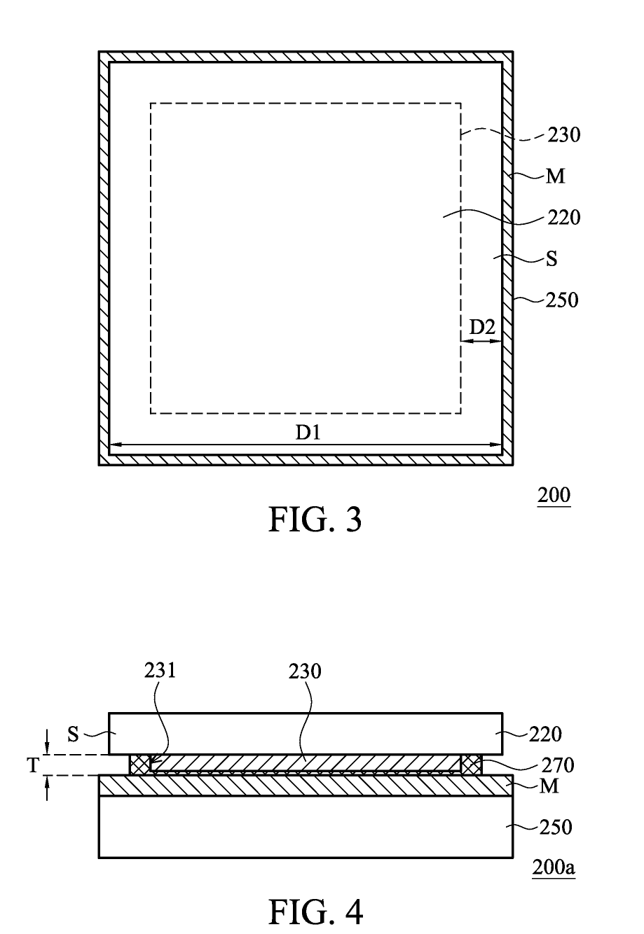

The light-emitting diode 200 fabricated using the above method includes the substrate 250, the metal layer M, the metal pad 230, and the epitaxial layer 220. The metal layer M is disposed on the substrate 250, and the metal pad 230 is disposed on the metal layer M. The epitaxial layer 220 is disposed on the metal pad 230, and the edges of the epitaxial layer 220 protrude out from the metal pad 230, forming a suspended portion S. The distance T between the suspended portion S and the metal layer M is for example 500-5000 angstroms, and the suspended portion S has for example a shape of a ring (as shown in FIG. 3). In addition, the width of the epitaxial layer 220 is D1, and the width of the ring is D2. In an embodiment, 0.1×D1>D2>0.05×D1.

In the fabrication method of light-emitting diodes of this embodiment, a stress release ring 240 is formed, and the stress release ring 240 is removed after performing a substrate replacement process so that the epitaxial layer 220 has a suspended portion S. Since a gap is present between the suspended portion S and the metal layer M, when the epitaxial layer 220 is heated, the suspended portion S has sufficient room for expansion, which reduces the residual stress in the epitaxial layer 220 caused by thermal expansion and contraction. Therefore, the light-emitting diode 200 of this embodiment has superior characteristics and a longer lifespan.

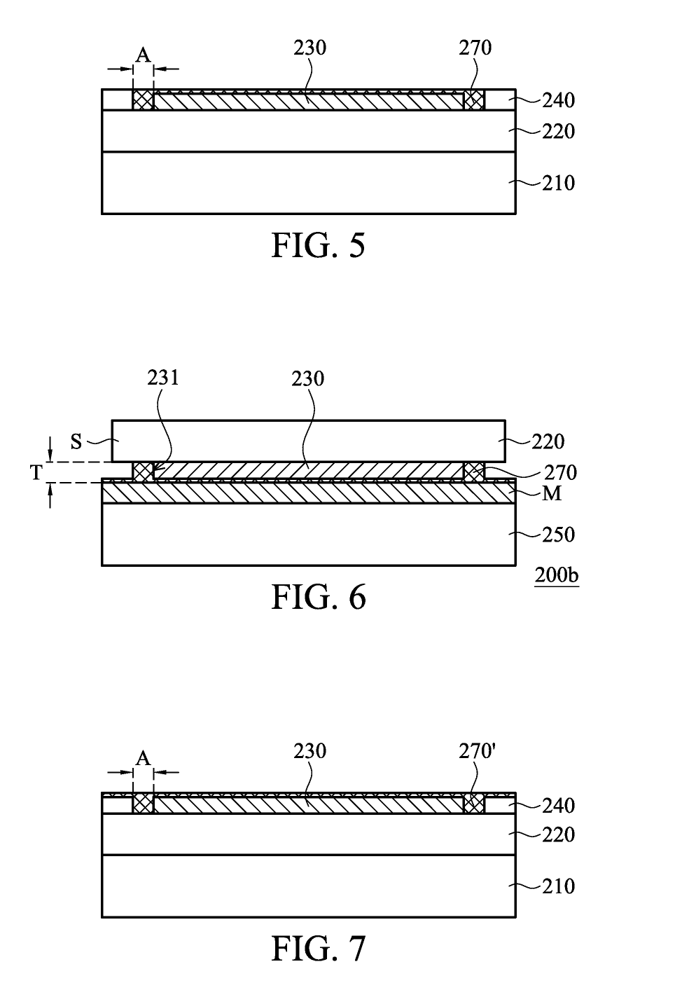

FIG. 4 illustrates a light emitting diode according to another embodiment of the invention, and FIG. 5 illustrates one of the steps of a fabrication method of the light-emitting diode according to another embodiment of the invention. Referring to FIG. 4, compared with the light-emitting diode 200 shown in FIG. 2E, the light-emitting diode 200a of this embodiment further includes a barrier layer 270 disposed between the metal pad 230 and the metal layer M. The barrier layer 270 covers edges 231 of the metal pad 230 but does not extend further than the suspended portion S. Therefore, the suspended portion S of the epitaxial layer 220 protrudes out from the barrier layer 270. Further, the distance T between the suspended portion S of the epitaxial layer 220 and the metal layer M is 500-5000 angstroms. The barrier layer 270 may be formed of titanium tungsten, a platinum-tungsten alloy, or a nickel-titanium tungsten alloy, but it may also be formed of other materials.

Referring FIG. 5, the barrier layer 270 described above is formed after forming the metal pad 230 and the stress release ring 240. The barrier layer 270 covers the metal pad 230. In addition, a gap A may be present between the metal pad 230 and the stress release ring 240, and the barrier layer 270 is filled into the gap A between the metal pad 230 and the stress release ring 240. In addition, in this embodiment, the substrate replacement process, the patterning process of the epitaxial layer 220, and the removal process of the stress release ring 240 mentioned above are implemented after forming the barrier layer 270 for obtaining the light emitting diode 200a shown in FIG. 4.

In this embodiment, the barrier layer 270 disposed between the metal pad 230 and the metal M may prevent the cross diffusion effect of metals, and the portion of the barrier layer 270 surrounding the metal pad 230 may prevent the electro migration of metals, which in turn, prevents the optoelectronic characteristics of the light emitting diode 200a from being damaged. In addition, the metal pad 230 may also be used as a reflective layer for reflecting light emitted from the epitaxial layer 220, thus improving the light utilization efficiency.

FIG. 6 illustrates a light-emitting diode according to another embodiment of the invention, and FIG. 7 illustrates one of the steps of a fabrication method of the light-emitting diode according to another embodiment of the invention. Referring to FIG. 6., the light-emitting diode 200b of the invention is similar to the light-emitting diode 200a shown in FIG. 4 except for the shape of the barrier layer 270′. In this embodiment, a portion of the barrier layer 270′ further extends below the suspended portion S of the epitaxial layer 220. Further, the distance T′ between the suspended portion S of the epitaxial layer 220 and the barrier layer 270′ is 500-5000 angstroms.

Referring to FIG. 7, the barrier layer 270′ described above is formed after forming the metal pad 230 and the stress release ring 240. The barrier layer 270′ covers the metal pad 230 and fills into the gap A between the metal pad 230 and the stress release ring 240. In addition, the barrier layer 270′ further covers the stress release ring 240. In addition, in this embodiment, the substrate replacement process, the patterning process for the epitaxial layer 220, and the removal process of the stress release ring 240 described above are implemented after forming the barrier layer 270 for obtaining the light-emitting diode 200b shown in FIG. 6.

The advantages of the light-emitting diode 200b fabricated by the fabrication method of this embodiment is similar to that of light-emitting diode 200a and hence will not be repeated here.

In summary, in the fabrication method of light-emitting diodes of the invention, a stress release ring is formed first, and then a substrate replacement process is implemented, which is followed by the removal of the stress release ring for obtaining an epitaxial layer with a suspended portion. Since the epitaxial layer of the light-emitting diode fabricated according to the invention has a suspended portion, when the epitaxial layer expands due to heat, the suspended portion has sufficient room for expansion, thus reducing the residual stress in the epitaxial layer due to thermal expansion and contraction. Therefore, the light-emitting diode 200 of this embodiment has superior characteristics and a longer lifespan. In addition, the barrier layer may prevent cross diffusion and electro migration of metals from damaging the optoelectronic characteristics of the light-emitting diode of the invention. In addition, the metal pad may be used as a reflective layer for increasing the light utilization efficiency of the light-emitting diode of the invention.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fabrication method of a light-emitting diode, comprising:
forming an epitaxial layer on a first substrate;
forming a metal pad and a stress release ring on the epitaxial layer, wherein the stress release ring surrounds the metal pad;
performing a substrate replacement process to transfer the epitaxial layer, the metal pad, and the stress release ring onto a second substrate, wherein the metal pad and the stress release ring are disposed between the epitaxial layer and the second substrate;
patterning the epitaxial layer to expose a portion of the stress release ring; and
removing the stress release ring to suspend a portion of the epitaxial layer.

2. The fabrication method of a light-emitting diode as claimed in claim 1, further comprising, before the substrate replacement process, forming a barrier layer covering the metal pad and filling into a gap between the metal pad and the stress release ring.

3. The fabrication method of a light-emitting diode as claimed in claim 1, wherein the barrier layer further covers the stress release ring.

4. The fabrication method of a light-emitting diode as claimed in claim 1, wherein the metal pad is a reflective layer.

5. The fabrication method of a light-emitting diode as claimed in claim 1, wherein the metal pad is in contact with the stress release ring.

6. The fabrication method of a light-emitting diode as claimed in claim 1, wherein a thickness of the stress release ring is 500-5000 angstroms.

7. The fabrication method of a light-emitting diode as claimed in claim 1, wherein the stress release ring is formed of a material selected from the group consisting of silicon dioxide, silicon nitride, photoresist, sol-gel, silicon, and aluminum oxide.

8. The fabrication method of a light-emitting diode as claimed in claim 1, wherein the suspended portion of the epitaxial layer has a shape of a ring.

9. The fabrication method of a light-emitting diode as claimed in claim 8, wherein a thickness of the epitaxial layer is D1, and a width of the ring is D2, wherein 0.1×D1>D2>0.05×D1.

10. The fabrication method of a light-emitting diode as claimed in claim 1, wherein the substrate replacement process comprises:
forming a metal layer on the metal pad and the stress release ring, and forming another metal layer on the second substrate;
bonding the metal layer on the metal pad and the stress release ring to the metal layer on the second substrate; and
removing the first substrate.

11. A light-emitting diode, comprising:
a substrate;
a metal layer disposed on the substrate;
a metal pad disposed on the metal layer; and
an epitaxial layer disposed on the metal pad, wherein edges of the epitaxial layer protrude out from the metal pad, forming a suspended portion.

12. The light-emitting diode as claimed in claim 11, wherein a distance between the suspended portion of the epitaxial layer and the metal layer is 500-5000 angstroms.

13. The light-emitting diode as claimed in claim 11, wherein the suspended portion of the epitaxial layer has a shape of a ring.

14. The light-emitting diode as claimed in claim 13, wherein a width of the epitaxial layer is D1, and a width of the ring is D2, wherein 0.1×D1>D2>0.05×D1.

15. The light-emitting diode as claimed in claim 11, further comprising a barrier layer disposed between the metal pad and the metal layer and covering edges of the metal pad, wherein the suspended portion of the epitaxial layer protrudes out from the barrier layer.

16. The light-emitting diode as claimed in claim 11, further comprising a barrier layer disposed between the metal pad and the metal layer and covering edges of the metal pad, wherein a portion of the barrier layer extends below the suspended portion of the epitaxial layer, and a distance between the suspended portion of the epitaxial layer and the barrier is 500-5000 angstroms.

17. The light-emitting diode as claimed in claim 11, wherein the metal pad is a reflective layer.
